(19) United States
(12) Patent Application Publication
(10) Pub. No.: US 2023/0161558 A1
(43) Pub. Date: May 25, 2023

(54) METHOD AND APPARATUS WITH QUANTIZATION SCHEME IMPLEMENTATION OF ARTIFICIAL NEURAL NETWORK

(71) Applicants: Samsung Electronics Co., Ltd., Suwon-si (KR); UNIST(ULSAN NATIONAL INSTITUTE OF SCIENCE AND TECHNOLOGY), Ulsan (KR)

(72) Inventors: JUN-WOO JANG, Suwon-si (KR); Jaewoo PARK, Ulsan (KR); Faaiz ASIM, Ulsan (KR); Jongeun LEE, Ulsan (KR)

(73) Assignees: Samsung Electronics Co., Ltd., Suwon-si (KR); UNIST(ULSAN NATIONAL INSTITUTE OF SCIENCE AND TECHNOLOGY), Ulsan (KR)

(21) Appl. No.: 17/986,303

(22) Filed: Nov. 14, 2022

(30) Foreign Application Priority Data
Nov. 24, 2021 (KR) 10-2021-0163588

(51) Int. Cl. G06F 7/544; G06F 7/50; G06F 5/01; H03K 19/21

(52) U.S. Cl. CPC G06F 7/5443; G06F 7/50; G06F 5/01; H03K 19/21

(57) ABSTRACT

A processor-implemented artificial neural network quantization scheme implementation method and apparatus are provided. The method includes receiving input data corresponding to a first M-dimensional vector, receiving a weight parameter corresponding to a second M-dimensional vector, encoding the input data into first bit streams, each having “N” layers, with a predetermined quantization scheme, encoding the weight parameter into second bit streams, each having “N” layers, with the quantization scheme, applying corresponding first and second bit streams to a binary neural network operator, for each of possible combinations between layers of the first bit streams and layers of the second bit streams, receiving a dot product result output based on a result obtained by shifting a BNN operation result corresponding to each of the combinations by a number of corresponding bits and accumulating the shifted BNN operation result, from the BNN operator, and quantizing the dot product result using the quantization scheme.

### CROSS-REFERENCE TO RELATED APPLICATIONS

This application claims the benefit under 35 USC §119(a) of Korean Patent Application No. 10-2021-0163588, filed on Nov. 24, 2021, in the Korean Intellectual Property Office, the entire disclosure of which is incorporated herein by reference for all purposes.

### BACKGROUND

### 1. Field

The following description relates to a method and apparatus with quantization scheme implementation of an artificial neural network.

### 2. Description of Related Art

Quantization technology is a method that increases power efficiency while reducing the amount of computational operation in the field of artificial intelligence. Quantization includes various technologies that convert input values expressed in accurate and fine units into values in more simplified units. Quantization technology may be implemented to reduce the number of bits necessary to represent information.

Typically, an artificial neural network may include an active node, a connection between nodes, and a weight parameter associated with each connection. The weight parameter and the active node may be quantized. If a neural network is executed in hardware, multiplication and addition operations may be performed millions of times.

If a lower-bit mathematical operation is performed with quantized parameters and if an intermediate calculation value of the neural network is also quantized, both an operation speed and performance may increase. Additionally, if the artificial neural network is quantized, a memory access may be reduced and an operation efficiency may be increased, thereby increasing a power efficiency.

However, an accuracy of the artificial neural network may decrease due to quantization. Accordingly, may increase the operation efficiency and the power efficiency, instead of having an influence on the accuracy.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a processor-implemented artificial neural network quantization scheme implementation method includes receiving input data corresponding to a first M-dimensional vector; receiving a weight parameter corresponding to a second M-dimensional vector; encoding the received input data into first bit streams, each having “N” layers, based on a predetermined quantization scheme; encoding the received weight parameter into second bit streams, each having “N” layers, based on the predetermined quantization scheme; applying a corresponding first bit stream and a corresponding second bit stream to a binary neural network (BNN) operator, for each of possible combinations between layers of the first bit streams and layers of the second bit streams; receiving a dot product result output based on a result obtained by shifting a BNN operation result corresponding to each of the combinations by a number of corresponding bits and accumulating the shifted BNN operation result, from the BNN operator; and quantizing the dot product result based on the predetermined quantization scheme.

The applying of the corresponding first bit stream and the corresponding second bit stream to the BNN operator may include performing an XNOR operation between each of layers of one of the first bit streams and each of layers of one of the second bit streams in an alternating manner, with the BNN operator; and performing a popcount operation on each of results obtained by performing the XNOR operation.

The number of corresponding bits may be determined based on layers of the corresponding first bit streams and layers of the corresponding second bit streams calculated for the BNN operation result.

The predetermined quantization scheme may be a scheme in which at least one positive quantization level and at least one negative quantization level are completely symmetric to each other by excluding zero from quantization levels.

The received input data and the received weight parameter may be quantized based on the following equation: v_{bar}=clamp(round (v/s+0.5)−0.5, −2^{b-1}+0.5, 2^{b-1}−0.5), where v denotes the weight parameter or the input data, s denotes a step side to determine a quantization range of the quantization scheme, and b denotes a predetermined number of quantization bits.

The received weight parameter may be trained and determined through at least one of quantization-aware training, post-training quantization, or data-free quantization.

The method may include transmitting the quantized dot product result to a next node.

In a general aspect, an apparatus includes a plurality of registers; at least one XNOR operator; at least one popcounter; at least one shifter; and at least one accumulator, wherein the registers are configured to store first bit streams, into which input data corresponding to a first M-dimensional vector is encoded based on a predetermined quantization scheme, and store second bit streams, into which a weight parameter corresponding to a second M-dimensional vector is encoded based on the predetermined quantization scheme, each of the first bit streams and the second bit streams having “N” layers, wherein, for each of possible combinations between layers of the first bit streams and layers of the second bit streams: a corresponding XNOR operator is configured to perform an XNOR operation between a corresponding first bit stream and a corresponding second bit stream, a corresponding popcounter is configured to apply a popcount operation to a result of the XNOR operation, a corresponding shifter is configured to shift a result of the popcount operation by a number of bits corresponding to a corresponding combination, and a corresponding accumulator is configured to perform an accumulation operation on shifted results of popcount operations corresponding to the combinations, and wherein a dot product result between the input data and the weight parameter is output based on a result of the accumulation operation.

The XNOR operator may be configured to alternately perform an XNOR operation between each of layers of one of the first bit streams and each of layers of one of the second bit streams.

The popcounter may be configured to perform a popcount operation on each of results obtained by performing the XNOR operation.

The number of bits may be determined based on layers of corresponding first bit streams and layers of corresponding second bit streams calculated for a binary neural network (BNN) operation result.

The predetermined quantization scheme may be a scheme in which at least one positive quantization level and at least one negative quantization level are completely symmetric to each other by excluding zero from quantization levels.

The input data and the weight parameter may be quantized based on the following equation: v_{bar}=clamp(round (v/s+0.5)−0.5, −2^{b-1}+0.5, 2^{b-1}−0.5), where v denotes the weight parameter or the input data, s denotes a step side for determining a quantization range of the quantization scheme, and b denotes a predetermined number of quantization bits.

The weight parameter may be trained and determined through quantization-aware training.

The result of the accumulation operation may be quantized based on the predetermined quantization scheme and transmitted to a next node.

The corresponding first bit stream and the corresponding second bit stream may be applied to a binary neural network (BNN) operator for each of the possible combinations between the layers of the first bit streams and the layers of the second bit streams.

An XNOR-popcount operation may be alternately performed on each of an upper bit stream and a lower bit stream of the input data and each of an upper bit stream and a lower bit stream of the weight parameter.

Other features and aspects will be apparent from the following detailed description, the drawings, and the claims.

### BRIEF DESCRIPTION OF DRAWINGS

FIGS. 1A and 1B are graphs illustrating examples of quantization parameters to which a quantization method is applied, in accordance with one or more embodiments.

FIGS. 2A, 2B, and 2C are graphs illustrating an example mapping probability of a range according to a quantization level, in accordance with one or more embodiments.

FIG. 3 is a flowchart illustrating an example method of operating an apparatus that implements a quantization scheme of an artificial neural network, in accordance with one or more embodiments.

FIG. 4 illustrates an example operation of an apparatus using data and quantization parameters, in accordance with one or more embodiments.

FIG. 5 is a block diagram illustrating a configuration of an apparatus that implements a quantization scheme of an artificial neural network.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of the application, may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for the purpose of describing particular examples only and is not to be limiting of the examples. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the examples with reference to the accompanying drawings, like reference numerals refer to like constituent elements and a repeated description related thereto will be omitted. In the description of examples, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the examples described above and an element having a common function. Unless otherwise mentioned, the descriptions on the examples may be applicable to the following examples and thus, duplicated descriptions will be omitted for conciseness.

To quantize weight parameters of an artificial neural network, a symmetric quantizer that is generally mapped to [−2^{(b-1)}, 2^{(b-1)}−1] may be used. In an example, b denotes a number of quantization bits. Performance of a quantized neural network (QNN) may be reduced when quantization with a low precision within 3 bits is performed. In a general quantization scheme, positive and negative quantization levels may be unequally assigned (e.g., −1, 0, 1, 2, etc.), which may lead to an occurrence of an error and a reduction in performance at a low-precision quantization level due to an asymmetry of positive and negative numbers. The neural network model may be configured to perform, as non-limiting examples, object classification, object recognition, and image recognition by mutually mapping input data and output data in a nonlinear relationship based on deep learning. Such deep learning is indicative of processor implemented machine learning schemes for solving issues, such as issues related to automated image or speech recognition from a data set, as non-limiting examples.

To implement an artificial neural network, a model including nodes and a connection network of the nodes may be realized through a multiplication in an activation function and a large number of multiply-accumulate (MAC) operations of summing multiplication values of weights and transmitting the sum to a single node (or neuron) in inference and training. A size of MAC operations may be determined in proportion to a size of the artificial neural network, and output data and data of an operand required for MAC may be stored in a memory in which the artificial neural network is implemented. However, such reference to “neurons” is not intended to impart any relatedness with respect to how the neural network architecture computationally maps or thereby intuitively recognizes information, and how a human's neurons operate. In other words, the term “neuron” is merely a term of art referring to the hardware implemented nodes of a neural network, and will have a same meaning as a node of the neural network.

Technological automation of pattern recognition or analyses, for example, has been implemented through processor implemented neural network models, as specialized computational architectures, that after substantial training may provide computationally intuitive mappings between input patterns and output patterns or pattern recognitions of input patterns. The trained capability of generating such mappings or performing such pattern recognitions may be referred to as a learning capability of the neural network. Such trained capabilities may also enable the specialized computational architecture to classify such an input pattern, or portion of the input pattern, as a member that belongs to one or more predetermined groups. Further, because of the specialized training, such specially trained neural network may thereby have a generalization capability of generating a relatively accurate or reliable output with respect to an input pattern that the neural network may not have been trained for, for example.

In the implementation of the artificial neural network, a MAC operator and a memory may be in the form of hardware. In a narrow sense, parallel implementation of a MAC operation and a memory mapped to hardware may be regarded as a hardware-type implementation of an artificial neural network, however, an efficiency of a multiplier and an adder used in a MAC operation may be increased or memory usage may be reduced.

In an example a binary neural network (BNN) may be provided as a scheme to increase a memory and computation costs of a deep neural network (DNN). The BNN may quantize a value of a parameter to +1 and −1 and express the value by 1 bit only, but a prediction accuracy may be relatively low.

Hardware of the BNN may implement a multiplication through an XNOR operation, which is a logical operation, and implement a cumulative addition through a popcount instruction to identify a number of bits set to “1” in a register. The BNN may improve an operation speed, because there is no need for multiplication and addition between real numbers or integers. Additionally, since the number of bits is reduced from an existing 32 bits to 1 bit, a memory bandwidth may theoretically increase by 32 times.

The BNN may perform an XNOR operation after converting both an input and a weight into 1 bit. A loss caused by conversion from 32 bits to 1 bit may be compensated for by multiplying an XNOR operation result by an approximate value. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

Examples may provide a quantization method that may implement efficient hardware for a deep neural network using a bit operation in BNN hardware.

A parameter level of typical linear quantization (CLQ) may be expressed as [−2^(b−1), 2^(b−1)−1] according to a number of bits. In an example, 2 bits may be expressed as {−2, −1, 0, 1}. An asymmetry between an anode and a cathode may be inversely determined.

In reduced symmetric quantization (RSQ), quantization may be performed to levels “L=−2b−1+1” and “U=2b−1−1”, for example, {−1, 0, 1}, using one less quantization parameter than a level of an example, which may result in fully symmetric quantization around zero. In the RSQ, a number of quantization levels may decrease, which may result in a decrease in performance.

In extended symmetric quantization (ESQ), fully symmetric quantization around zero may be realized using one or more quantization levels, and 2 bits or more may be requested. Quantization may be performed to levels “L=−2b−1” and “U=2b−1”, for example, {−2, −1, 0, 1, 2}.

Non-uniform symmetric quantization (NSQ) may include a symmetric form in which 2b quantization levels do not include zero. In an example, a scheme of performing quantization to {−2, −1, 1, 2} may be provided, however, ranges between quantization levels may not be uniform.

In a quantization method according to examples, a uniform range between parameters, and a symmetric structure between positive numbers and negative numbers may be provided, and zero may not be included as a quantization level. In other words, zero may be excluded from quantization levels, and positive quantization levels and negative quantization levels may be completely symmetric to each other. In an example, a step size for a quantization range may be determined as “2” to perform quantization to fractional levels such as {−1.5, −0.5, 0.5, 1.5} and quantization to an integer such as {−3, −1, 1, 3}.

In an example, if an artificial neural network is trained, a parameter and a quantization range of the parameter may be trained together. Various training schemes developed for linear quantization may be applied to a training scheme according to examples. Quantization-aware training (QAT) may be applied for training on quantized parameters. In an example, a quantization range may be trained in the same manner as learned step-size quantization (LSQ). Centered Symmetric Quantization (CSQ) may not be limited to QAT because it has mostly to do with resulting quantization levels, whether obtained from QAT or post-training quantization (PTQ or even data-free quantization (DFQ).

In an example, to learn such symmetrical quantization parameters, a differentiation formula such as Equation 1 below may be used.

$$\frac{\partial v}{\partial s} = \{ \begin{matrix}- \frac{v}{s} + ( ⌈ \frac{v}{s} ⌉ - 0.5 ) & if - {Q}_{n} < ( ⌈ \frac{v}{s} ⌉ - 0.5 ) \leq {Q}_{p} \\ {Q}_{n} & if ( ⌈ \frac{v}{s} ⌉ - 0.5 ) \leq {Q}_{n} \\ {Q}_{p} & if ( ⌈ \frac{v}{s} ⌉ - 0.5 ) \geq {Q}_{p}\end{matrix} \qquad Equation 1$$

To optimize a step size s of a quantization range using a gradient descent scheme, the differentiation formula such as Equation 1 above may be used. In Equation 1, v denotes an input value, Qn denotes an absolute value of a minimum value of a quantization range, and Qp denotes a maximum value of the quantization range.

The gradient descent scheme may be used to reduce a loss function through a change in a gradient of a real function, and may include a process of reducing an error by obtaining a gradient for an initial point in time and converging the gradient through a process of movement in an opposite direction of the gradient. In an example, a converged loss gradient may be calculated.

A gradient of the step size may be scaled to

$$g = 1 / \sqrt{{N}_{W} {2}^{p}} ,$$

similar to a scaling of a gradient. In an example, g denotes scaling of a step size, N_{w} denotes a number of quantization parameters, and p denotes a bit-width.

In an example, a weight may be initialized to

$$2 〈 \vert v \vert 〉 / \sqrt{Q} .$$

In an example, <.>may be used as a scheme of indicating a mean of a distribution.

In an example, a quantization scheme obtained through training may be expressed as shown in Equation 2 below.

$$\hat{v} = ⌊ \frac{v}{s} + 0.5 ⌉ - 0.5 \\ \overline{v} = clip ( \dot{v} , - Q , Q ) \\ \hat{v} = \overline{v} \times s \qquad Equation 2$$

In Equation 2, a clip( ) function may be represented as clip(list, minimum value, maximum value) and may return an array in which values in a list are converted into values between a minimum value and a maximum value, and clip(x; a; b)=min(max(x; a); b) may be expressed.

In an example, v denotes an arbitrary input value, and s denotes the step size. Through the above training, “Q=2^{b-1}−0.5” in which b denotes a quantization density, that is, a predetermined number of bits, may be determined. Additionally, although v is not an integer, v may be more accurately expressed through a b-bit quantization method according to an example. Additionally, [symbol] denotes a value calculated in b-bit hardware, and [symbol] corresponds to a reduced version of v defined and used for training. A quantization apparatus according to an example may be equally expressed for a positive number and a negative number of an input distribution.

In an example, the quantization method may be implemented in efficient hardware and software, which will be described in detail later.

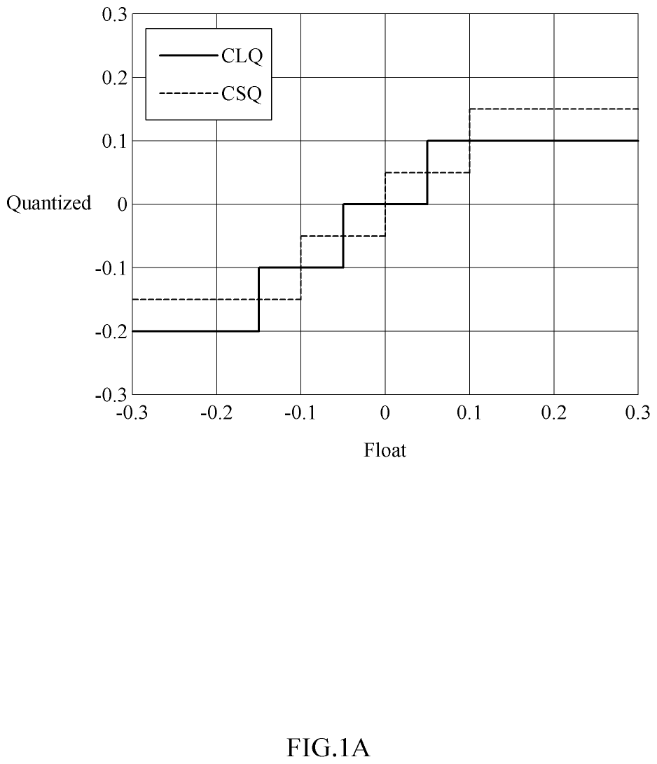

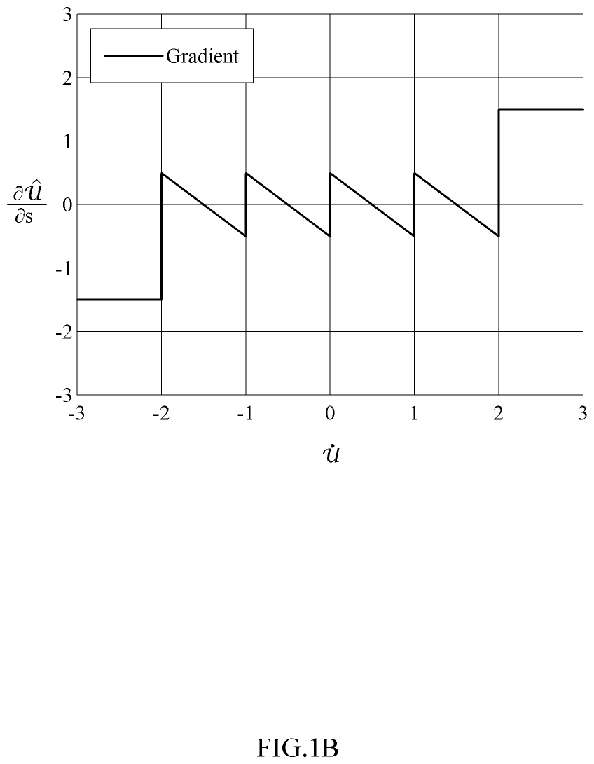

FIGS. 1A and 1B are graphs illustrating examples of quantization parameters to which a quantization method is applied, in accordance with one or more embodiments.

FIG. 1A illustrates results according to a general linear quantization method and a quantization method according to an example, and FIG. 1B is a graph showing a gradient for a step size of a quantization parameter according to an example.

A graph of FIG. 1A relates to an example in which 2-bit data is quantized. Referring to FIG. 1A, results of quantizing values around zero for the linear quantization method with the same step size may be different from each other, and quantization may be possible in a form in which upper and lower ranges are equal with respect to zero in the quantization method according to the example. A rounding operator may be applied to all input values, except portions in which an input is an integer.

The graph according to the example is shown based on a quantization range determined by a step size optimized through the above-described gradient descent scheme. As shown in FIG. 1B, it can be found that a quantization result may be obtained within a predetermined gradient with respect to an input value included in a quantization range by the quantization method according to the example.

The quantization method according to the example may be implemented in hardware and software having an efficiency close to maximum entropy in a low-bit quantized weight, for example, 3 bits or less.

A typical example may be a BNN. Although the BNN is an innovative scheme in that the BNN may significantly increase a speed of an existing artificial neural network and significantly reduce a memory capacity of an artificial neural network model as described above, a loss of information may occur because existing floating-point weights and activation functions are expressed as “−1” and “1”. The above loss of information may result in a decrease in an accuracy, thereby reducing performance when an object is recognized or detected.

The quantization method according to the examples may be efficiently mapped to BNN hardware. Binary weights, for example, weight parameters of “+1” and “−1” may be applied through the BNN. By applying the above weight parameters, a multiplier may be eliminated when implemented in hardware. Also, a high operation speed may be provided by simplifying a neural network structure.

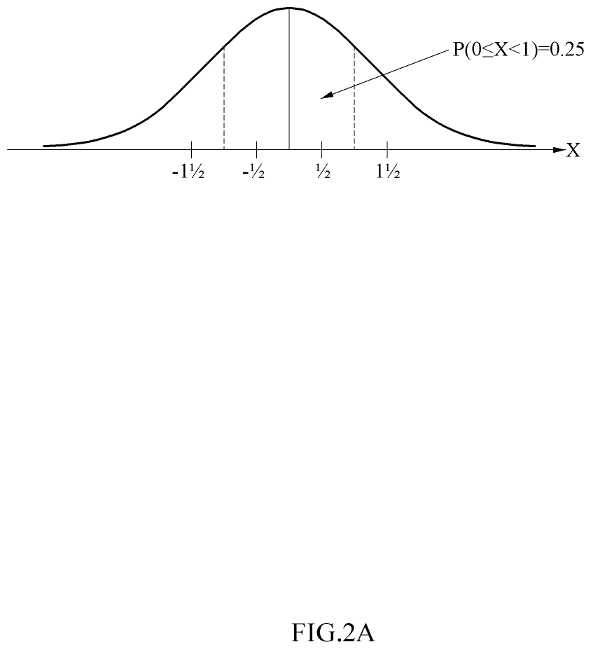

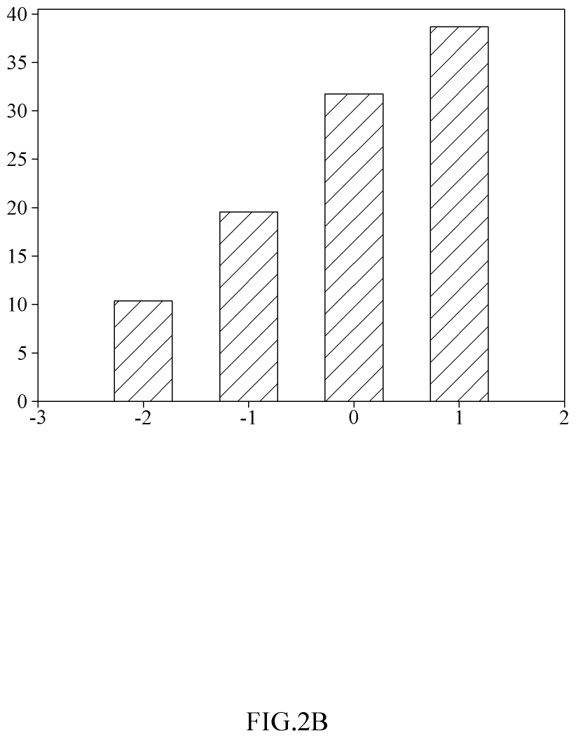

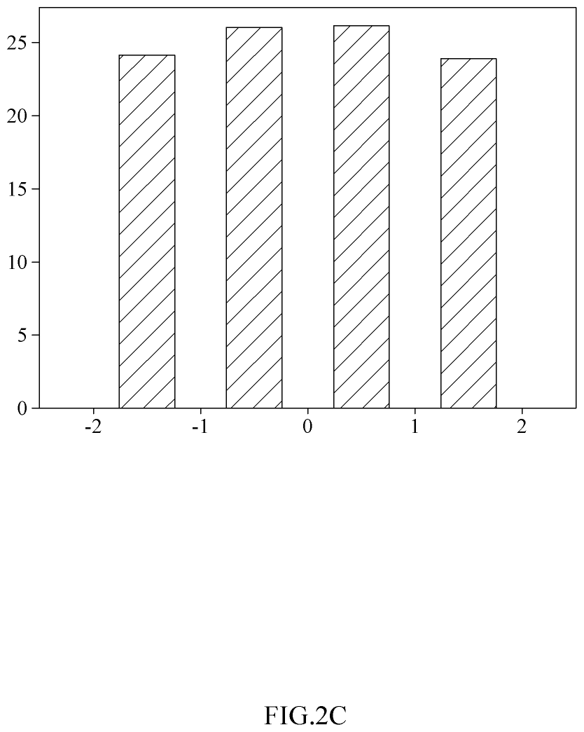

FIGS. 2A to 2C illustrate an example of a probability distribution of a quantization range quantized to 2 bits.

FIG. 2A is a graph illustrating a normal distribution of ranges according to quantization levels, in accordance with one or more embodiments.

Referring to FIG. 2A, an x-axis represents a quantization level, and a y-axis represents a probability distribution for each actual data. In an example, the normal distribution may be similar to a Gaussian distribution.

A quantization method according to an example may be used to maximize an efficiency according to a quantization level through quantization.

In an example in which data is quantized, when data mapped for each quantization level needs to be distributed as uniformly as possible, a high quantization efficiency may be provided, or when a distribution of quantization levels is similar to a data distribution, for example, a Gaussian distribution, a high quantization efficiency may be provided.

The quantization method according to the example may satisfy both the above two conditions. In an example, if quantization is performed to 2 bits according to an example, in general, the above two conditions may be satisfied based on a threshold {−1; 0; 1}.

In an example, data may be uniformly distributed over the quantization levels as shown in FIG. 2A, and at the same time, the quantization levels may also follow the Gaussian distribution. In this example, it may be assumed that the Gaussian distribution of FIG. 2A follows a cumulative distribution function (CDF) of a standard normal distribution represented by P(0≤X≥s)=0:25 in X˜N(0; 1).

FIGS. 2B and 2C are graphs illustrating a probability of actual data being mapped by CLQ and a probability of actual data being mapped by a quantization method according to an example, respectively.

FIG. 2B illustrates a mapping probability of actual data being mapped to a quantization level trained and determined by CLQ, and FIG. 2C illustrates a mapping probability of actual data being mapped to a quantization level trained and determined by the quantization method according to the example.

As illustrated in FIG. 2B, quantization levels may correspond to (−2, −1, 0, 1), and mapping probabilities for each quantization level may range from 10% to 40%, and thus it may be difficult to evaluate a quantization efficiency to be good. However, in FIG. 2C, mapping probabilities may appear relatively uniform around 25% for each of quantization levels −1.5, −0.5, 0.5, and 1.5.

A method of implementing the above quantization method in hardware will be described in detail.

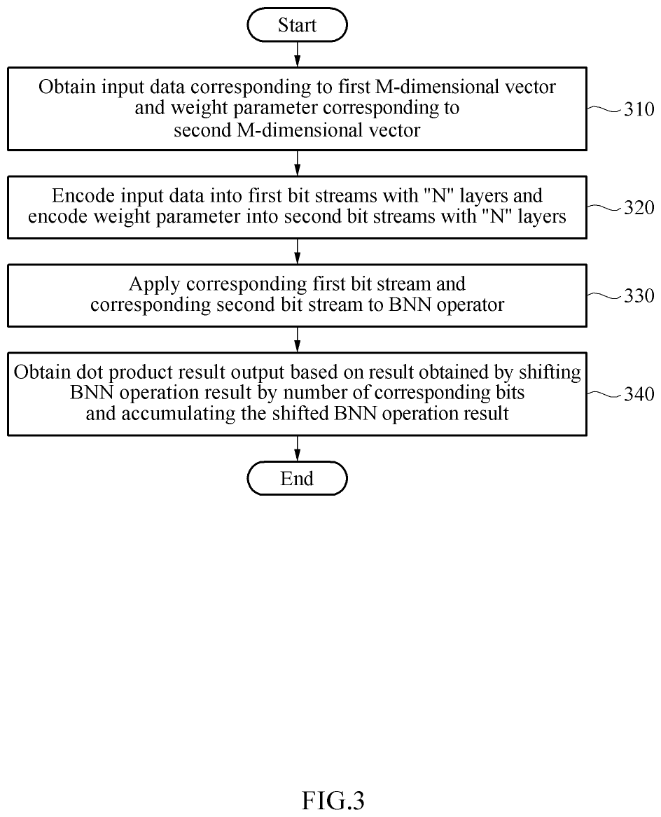

FIG. 3 is a flowchart illustrating an example method of operating an apparatus to implement a quantization scheme of an artificial neural network, in accordance with one or more embodiments. The operations in FIG. 3 may be performed in the sequence and manner as shown, although the order of some operations may be changed or some of the operations omitted without departing from the spirit and scope of the illustrative examples described. Many of the operations shown in FIG. 3 may be performed in parallel or concurrently. One or more blocks of FIG. 3, and combinations of the blocks, can be implemented by special purpose hardware-based computer that perform the specified functions, or combinations of special purpose hardware and computer instructions. In addition to the description of FIG. 3 below, the descriptions of FIGS. 1-2C are also applicable to FIG. 3, and are incorporated herein by reference. Thus, the above description may not be repeated here.

In operation 310, the apparatus may obtain input data and a weight parameter.

In an example, one or more nodes constituting an artificial neural network may perform an operation corresponding to a node of one cycle. Input data and a weight parameter input to a corresponding node may be assumed to correspond to M-dimensions.

The input data and the weight parameter may be represented by a first M-dimensional vector and a second M-dimensional vector, respectively. The input data may correspond to output data of a previous node.

In operation 320, the apparatus may encode each of the input data and the weight parameter into bit streams, each having “N” layers, using a predetermined quantization scheme.

In an example, a bit stream obtained by encoding the input data may be referred to as a “first bit stream”, and a bit stream obtained by encoding the weight parameter may be referred to as a “second bit stream”.

The predetermined quantization scheme may include, for example, the quantization scheme described with reference to FIGS. 1A to 2C. Each of input data and a quantization parameter may be encoded into “N” bit streams.

In an example, when binary encoding is performed in a BNN, “0” may be interpreted as “−1”, instead of a general 2′ complement scheme. In an example, 010 may be encoded to −1, 1, −1, and a corresponding input may be expressed as −(2^2)+(2^1)−(2^0)=−3.

In an example, a number of bit streams obtained by encoding may be determined based on a number of quantization levels. In an example, when four quantization levels are provided, each of the input data and the weight parameter may be encoded into two bit streams, and when eight quantization levels are provided, each of the input data and weight parameter may be encoded into three bit streams.

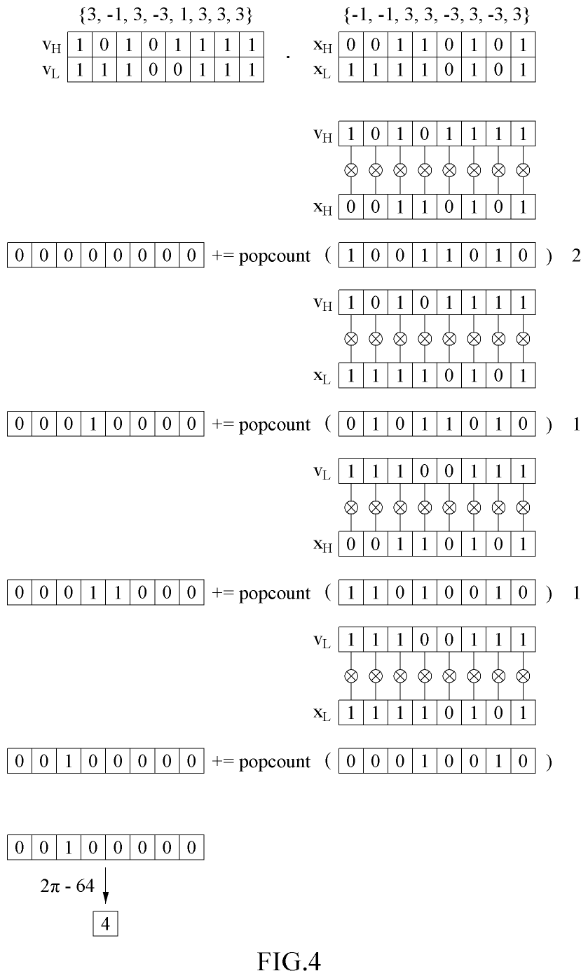

FIG. 4 illustrates an operation of an example apparatus using input data and weight parameters.

Referring to FIG. 4, {3, −1, 3, −3, 1, 3, 3, 3} may correspond to input data, and {−1, −1, 3, 3, −3, 3, −3, 3} may correspond to weight parameters. Each of the input data and the weight parameters may be 8-dimensional data. The input data {3, −1, 3, −3, 1, 3, 3, 3} may encoded into binary numbers expressed as {11, 01, 11, 00, 10, 11, 11, 11}, and an upper bit stream corresponding to v_{H}={1, 0, 1, 0, 1, 1, 1, 1} and a lower bit stream corresponding to v_{L}={1, 1, 1, 0, 0, 1, 1, 1} may be separately expressed according to the number of digits. Similarly, the weight parameters {−1, −1, 3, 3, −3, 3, −3, 3} may be encoded into {01, 01, 11, 11, 00, 11, 00, 11}, and x_{H}={0, 0, 1, 1, 0, 1, 0, 1} and x_{L}={1, 1, 1, 1, 0, 1, 0, 1} may be expressed according to the number of digits.

The above encoding scheme may be extended even in the case of 3 bits. In the example of 3 bits, each of input data and a weight parameter may be expressed as three bit streams.

Referring back to FIG. 3, in operation 330, the apparatus may apply a corresponding first bit stream and a corresponding second bit stream to a BNN operator, for each of possible combinations between layers of first bit streams and layers of second bit streams.

In operation 340, the apparatus may obtain, from the BNN operator, a dot product result output based on a result obtained by shifting a BNN operation result corresponding to each of the combinations by a number of corresponding bits and accumulating the shifted BNN operation result.

An operation result may be obtained by performing an XNOR operation and popcount on possible combinations between layers constituting each of bit streams obtained by encoding, using the BNN operator. In an example, the apparatus may apply an XNOR-popcount scheme of the BNN operator to perform a MAC operation. The above hardware implementation may be easy to remove an additional bit for sign extension. In an example, hardware for implementing a corresponding quantization method using a shifter, an accumulator and a parallel connection of a plurality of BNN operators may be provided.

Hereinafter, an equation to induce a MAC operation of 2-bit binary data to hardware of a BNN operator will be described.

A 2-bit binary number x=x1x0 may represent an integer and may be expressed as X=2*(−1)^x1+(−1)^x0. A 2-bit binary number y=y1y0 may represent an integer and may be expressed as Y=2*(−1)^y1+(−1)^y0.

A product of X and Y may be represented by XY=4*(−1)^(x1+y1)+2*(−1)^(x0+y1)+2*(−1)^(x1+y0)+(−1)^(x0+y0).

In an example of a 1-bit binary number x, y, z=xnor(x, y), Z=(−1)^z, X=(−1)^x, and Y=(−1)^y, and accordingly XY=−Z. If a corresponding equation is calculated, XY=(−1)^(x+y)^(−1)^xor(x, y)=(−1)^[1+xnor(x, y)]=−1*(−1)^xnor(x, y)=−Z may be obtained.

In addition, in quantization encoding according to an example, Z=2*z−1, and as a result, XY=1−2z=1−2 xnor(x,y).

Accordingly, XY may be expressed again using XNOR-popcount below.

XY=4*(1−2xnor(x1, y1))+2*(1−2xnor(x0, y1))+2*(1−2xnor(x1, y0))+(1−2xnor(x0, y0))=9−8xnor(x1, y1)−4(xnor(x0, y1)+xnor(x1, y0))−2 xnor(x0, y0)

Thus, a 2-bit XY product may be calculated using four XNOR operations, three shift operations (2 bits), and four addition operations. In an example, further simplification may be achieved by combining a constant term with a bias term and dividing all terms by “2”. In this example, only four XNOR operations, two shift operations, and three addition operations may be required.

In other words, an N-bit quantization scheme may be implemented using N² parallel or serial connections of 1-bit BNNs.

The quantization encoding may be more efficient for a 2-bit dot product. In quantization, 2-bit×2-bit multiplication and 1-bit×2-bit multiplication may be performed in XNOR-popcount BNN hardware even though additional hardware (e.g., a signed or unsigned multiplier) is not added.

In an example, an XNOR operation between each of bit streams of input data input through BNN hardware connected in parallel and each of bit streams of a weight parameter may be performed in an alternating manner, and popcount may be performed on each of results obtained by performing XNOR operations.

In an example, each of result values obtained by performing the XNOR operation and popcount may be shifted by a predetermined number of bits. In an example, the number of bits may be determined based on a layer of a bit stream on which an operation is performed.

Hereinafter, an example in which an operation is performed through hardware according to an example will be described with reference to FIG. 4.

In an example, XNOR-popcount may be performed on each of an upper bit stream and a lower bit stream of input data and each of an upper bit stream and a lower bit stream of a weight parameter in an alternating manner.

In an example, if an XNOR operation between upper bit streams vH and xH is performed, {1, 0, 0, 1, 1, 0, 1, 0} may be obtained, and if popcount is performed on corresponding bit streams, {0, 0, 0, 0, 0, 1, 0, 0} may be obtained. In an example, as described above, shift by 2 bits may be performed for an operation between upper bit streams, and accordingly {0, 0, 0, 1, 0, 0, 0, 0} may be obtained.

In addition, {0, 1, 0, 1, 1, 0, 1, 0} and {1, 1, 0, 1, 0, 0, 1, 0} may be obtained through an XNOR operation of vH and xL and an XNOR operation of vL and xH, respectively. For each bit stream, {0, 0, 0, 0, 0, 1, 0, 0} may be obtained equally through popcount, and a shift by 1 bit may be set to obtain {0, 0, 0, 0, 1, 0, 0, 0}.

{0, 0, 0, 1, 0, 0, 1, 0} may be obtained through an XNOR operation of xL and vL, {0, 0, 0, 0, 0, 0, 1, 0} may be obtained by performing popcount on corresponding bit streams, and shift may not applied to the corresponding bit streams.

In an example, an accumulation operation may be performed on a bit stream on which XNOR-popcount is performed and on which shift operations are performed a predetermined number of times, for each bit stream. For example, as shown in FIGS. 4, {0, 0, 0, 1, 0, 0, 0, 0}, {0, 0, 0, 0, 1, 0, 0, 0}, {0, 0, 0, 0, 1, 0, 0, 0} and {0, 0, 0, 0, 0, 0, 1, 0} may be accumulated through an accumulator. Accordingly, {0, 0, 1, 0, 0, 0, 1, 0} may be finally output.

A similar scheme as described above may be applied to an example of performing XNOR-popcount on 3-bit data, to enable implementation through a shifter, an accumulator, and a BNN including an XNOR operator and a popcounter. For example, BNN hardware may be used 3² times, that is, 9 times.

In an example, since the example of 1 bit may be the same as a BNN, calculation may be performed through BNN hardware of XNOR-popcount.

In an example, if a bit stream {0, 0, 1, 0, 0, 0, 1, 0} calculated by the output of FIG. 4 is x, a final operation result may be output by calculating a value of “2×−64”. In this example, “64” may be derived from a dimension of input data and a weight parameter. In another example, {0, 0, 1, 0, 0, 0, 1, 0} may be expressed as a decimal number, that is, “34”, and a final output may be calculated as “4” by “34×2−64=4”.

In an example, the apparatus may quantize a dot product result using a predetermined quantization scheme.

In an example, a node constituting an artificial neural network may perform quantization to transmit a result value to a next node. A quantization level according to an example may correspond to {−3, −1, 1, 3}, and a final output of “4” may be quantized to “3”. A quantization result may be transmitted to the next node.

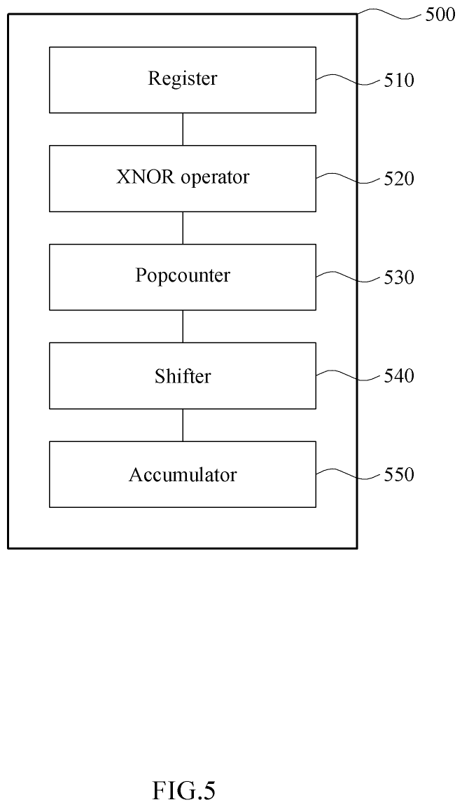

FIG. 5 illustrates an example apparatus for quantization, in accordance with one or more embodiments.

Referring to FIG. 5, an apparatus 500 may include a plurality of registers 510, an XNOR operator 520, a popcounter 530, a shifter 540, and an accumulator 550.

The apparatus 500 may further include a processor, a memory, and a communication interface. The processor, the memory, and the communication interface may communicate with each other via a communication bus.

The processor may control operations of the registers 510, the XNOR operator 520, the popcounter 530, the shifter 540, and the accumulator 550. In an example, the XNOR operator 520 and the popcounter 530 may be implemented through a BNN.

The registers 510 may store first bit streams into which input data corresponding to a first M-dimensional vector is encoded using a predetermined quantization scheme, and second bit streams into which a weight parameter corresponding to a second M-dimensional vector is encoded using the predetermined quantization scheme. Each of the first bit streams and the second bit streams may include “N” layers.

The XNOR operator 520 and the pop counter 530 may perform an XNOR operation between a corresponding first bit stream and a corresponding second bit stream, and perform a popcount operation on a result of the XNOR operation.

In an example, an XNOR operation between each of bit streams of input data input to BNN operators connected in parallel and each of bit streams of a weight parameter may be performed in an alternating manner, and popcount may be performed on each of results obtained by performing XNOR operations.

The shifter 540 may perform shift by bits corresponding to each of result values of an XNOR operation and popcount operation. The accumulator 550 may accumulate and sum shifted result values.

In an example, the apparatus 500 may provide a dot product result between the input data and the weight parameter based on a result of an accumulation operation.

The apparatus 500 may be connected to an external device (e.g., a personal computer (PC) or a network) through an input/output device (not shown) to exchange data therewith. The apparatus 500 may be mounted on various computing devices and/or systems such as a smartphone, a tablet computer, a laptop computer, a desktop computer, a television (TV), a wearable device, a security system, a smart home system, and the like.

A neural network operation apparatus of one or more embodiments may be configured to reduce the size of a neural network model while improving the neural network operation performance, thereby solving such a technological problem and providing a technological improvement by advantageously reducing costs and increasing a calculation speed of the neural network operation apparatus of one or more embodiments over the typical neural network apparatus. The examples may maximize an efficiency according to a quantization level through quantization.

The apparatus 500, the register 510, XNOR operator 520, popcounter 530, shifter 540, accumulator 550, and other apparatuses, units, modules, devices, and other components described herein and with respect to FIGS. 1-5, are implemented by hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods that perform the operations described in this application and illustrated in FIGS. 1-5 are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller, e.g., as respective operations of processor implemented methods. One or more processors, or a processor and a controller, may perform a single operation, or two or more operations.

Instructions or software to control computing hardware, for example, one or more processors or computers, to implement the hardware components and perform the methods as described above may be written as computer programs or instructions, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computers using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A processor-implemented artificial neural network quantization scheme implementation method, the method comprising:
receiving input data corresponding to a first M-dimensional vector;
receiving a weight parameter corresponding to a second M-dimensional vector;
encoding the received input data into first bit streams, each having “N” layers, based on a predetermined quantization scheme;
encoding the received weight parameter into second bit streams, each having “N” layers, based on the predetermined quantization scheme;
applying a corresponding first bit stream and a corresponding second bit stream to a binary neural network (BNN) operator, for each of possible combinations between layers of the first bit streams and layers of the second bit streams;
receiving a dot product result output based on a result obtained by shifting a BNN operation result corresponding to each of the combinations by a number of corresponding bits and accumulating the shifted BNN operation result, from the BNN operator; and
quantizing the dot product result based on the predetermined quantization scheme.

2. The method of claim 1, wherein the applying of the corresponding first bit stream and the corresponding second bit stream to the BNN operator comprises:
performing an XNOR operation between each of layers of one of the first bit streams and each of layers of one of the second bit streams in an alternating manner, with the BNN operator; and
performing a popcount operation on each of results obtained by performing the XNOR operation.

3. The method of claim 1, wherein the number of corresponding bits is determined based on layers of the corresponding first bit streams and layers of the corresponding second bit streams calculated for the BNN operation result.

4. The method of claim 1, wherein the predetermined quantization scheme is a scheme in which at least one positive quantization level and at least one negative quantization level are completely symmetric to each other by excluding zero from quantization levels.

5. The method of claim 1, wherein:
the received input data and the received weight parameter are quantized based on the following equation:
v_{bar}=clamp(round (v/s+0.5)−0.5, −2^{b-1}+0.5, 2^{b-1}−0.5),
where v denotes the weight parameter or the input data, s denotes a step side to determine a quantization range of the quantization scheme, and b denotes a predetermined number of quantization bits.

6. The method of claim 1, wherein the received weight parameter is trained and determined through at least one of quantization-aware training, post-training quantization, or data-free quantization.

7. The method of claim 1, further comprising:
transmitting the quantized dot product result to a next nPowerode.

8. A non-transitory computer-readable storage medium storing instructions that, when executed by a processor, cause the processor to perform the quantization method of claim 1.

9. An apparatus, comprising:
a plurality of registers;
at least one XNOR operator;
at least one popcounter;
at least one shifter; and
at least one accumulator,
wherein the registers are configured to store first bit streams, into which input data corresponding to a first M-dimensional vector is encoded based on a predetermined quantization scheme, and store second bit streams, into which a weight parameter corresponding to a second M-dimensional vector is encoded based on the predetermined quantization scheme, each of the first bit streams and the second bit streams having “N” layers,
wherein, for each of possible combinations between layers of the first bit streams and layers of the second bit streams:
a corresponding XNOR operator is configured to perform an XNOR operation between a corresponding first bit stream and a corresponding second bit stream,
a corresponding popcounter is configured to apply a popcount operation to a result of the XNOR operation,
a corresponding shifter is configured to shift a result of the popcount operation by a number of bits corresponding to a corresponding combination, and
a corresponding accumulator is configured to perform an accumulation operation on shifted results of popcount operations corresponding to the combinations, and
wherein a dot product result between the input data and the weight parameter is output based on a result of the accumulation operation.

10. The apparatus of claim 9, wherein the XNOR operator is configured to alternately perform an XNOR operation between each of layers of one of the first bit streams and each of layers of one of the second bit streams.

11. The apparatus of claim 10, wherein the popcounter is configured to perform a popcount operation on each of results obtained by performing the XNOR operation.

12. The apparatus of claim 9, wherein the number of bits is determined based on layers of corresponding first bit streams and layers of corresponding second bit streams calculated for a binary neural network (BNN) operation result.

13. The apparatus of claim 9, wherein the predetermined quantization scheme is a scheme in which at least one positive quantization level and at least one negative quantization level are completely symmetric to each other by excluding zero from quantization levels.

14. The apparatus of claim 9, wherein:
the input data and the weight parameter are quantized based on the following equation:
v_{bar}=clamp(round (v/s+0.5)−0.5, −2^{b-1}+0.5, 2^{b-1}−0.5),
where v denotes the weight parameter or the input data, s denotes a step side for determining a quantization range of the quantization scheme, and b denotes a predetermined number of quantization bits.

15. The apparatus of claim 9, wherein the weight parameter is trained and determined through at least one of quantization-aware training, post-training quantization, or data-free quantization.

16. The apparatus of claim 9, wherein the result of the accumulation operation is quantized based on the predetermined quantization scheme and transmitted to a next node.

17. The apparatus of claim 9, wherein the corresponding first bit stream and the corresponding second bit stream are applied to a binary neural network (BNN) operator for each of the possible combinations between the layers of the first bit streams and the layers of the second bit streams.

18. The apparatus of claim 9, wherein an XNOR-popcount operation is alternately performed on each of an upper bit stream and a lower bit stream of the input data and each of an upper bit stream and a lower bit stream of the weight parameter.
